(19) United States
(12) Patent Application Publication
(10) Pub. No.: US 2008/0117602 A1
(43) Pub. Date: May 22, 2008

(54) POWER INVERTER HAVING LIQUID COOLED CAPACITOR AND LOW INDUCTANCE BUS STRUCTURE

(76) Inventors: Mark D. Korich, Chino Hills, CA (US); David Tang, Fontana, CA (US); Mark L Selogie, Manhattan, CA (US); Young Doo, La Palma, CA (US)

Correspondence Address: GENERAL MOTORS CORPORATION;LEGAL STAFF, MAIL CODE 482-C23-B21, P O BOX 300, DETROIT, MI, 48265-3000, US

(21) Appl. No.: 11/561,499

(22) Filed: Nov. 20, 2006

(51) Int. Cl. H05K 7/20

(52) U.S. Cl. 361/715

(57) ABSTRACT

A power inverter is provided. The power inverter includes a housing having first and second openings therein and at least partially defining a cavity and a fluid passageway on first and second sides of the cavity. First and second power modules are connected to the housing on the respective first and second sides of the cavity. A capacitor assembly is within the cavity such that when heat is generated by the first and second power modules and the capacitor assembly and a fluid flows into the first opening, through the fluid passageway, and out of the second opening, at least some of the heat is transferred from the first and second power modules and the capacitor assembly to the fluid and is removed through the second opening.

### TECHNICAL FIELD

The present invention generally relates to a power inverter, and more particularly relates to a power inverter for use in an automobile.

### BACKGROUND OF THE INVENTION

In recent years, advances in technology, as well as ever evolving tastes in style, have led to substantial changes in the techniques used to design and build automobiles. One of the changes involves the complexity of the various electrical systems within automobiles. As a result, electrical systems in automobiles, especially hybrid vehicles, are using an ever increasing amount of electrical power.

Many of the electrical components, such as electric motors, used in such vehicles receive electrical power from alternating current (AC) power supplies. However, the power sources (i.e., batteries) used in such applications only provide direct current (DC) power. Thus, devices known as power inverters are used to convert the DC power to AC power.

Because of the large amounts of power involved, power inverters are often cooled with radiator systems. However, the operating temperatures of fluids in radiators used to cool combustion engines are generally too high to effectively cool conventional inverters. Thus, a separate radiator system is typically provided to cool the inverter. Additionally, as the power demands of the electrical systems in vehicles continue to increase, conventional power inverters are becoming increasingly inadequate due to their large size and limited performance.

Accordingly, it is desirable to provide a power inverter with improved cooling. In addition, it is desirable to provide a power inverter with reduced size and improved performance. Furthermore, other desirable features and characteristics of the present invention will become apparent from the subsequent detailed description and the appended claims, taken in conjunction with the accompanying drawings and the foregoing technical field and background.

### SUMMARY OF THE INVENTION

A vehicular power inverter is provided. The vehicular power inverter includes a housing having first and second openings therein and at least partially defining a cavity and a fluid passageway on first and second sides of the cavity. First and second power modules are connected to the housing on the respective first and second sides of the cavity. A capacitor assembly is within the cavity such that when heat is generated by the first and second power modules and the capacitor assembly and a fluid flows into the first opening, through the fluid passageway, and out of the second opening, at least some of the heat is transferred from the first and second power modules and the capacitor assembly to the fluid and is removed through the second opening.

An automobile is provided. The automobile includes a frame, an actuator connected to the frame, a power inverter coupled to the frame and the actuator, and a cooling system. The power inverter includes a housing having first and second openings therein and at least partially defining a cavity and a fluid passageway on first and second sides of the cavity. First and second power modules are connected to the housing on the respective first and second sides of the cavity. A capacitor assembly is within the cavity such that when heat is generated by the first and second power modules and the capacitor assembly and a fluid flows into the first opening, through the fluid passageway, and out of the second opening, at least some of the heat is transferred from the first and second power modules and the capacitor assembly to the fluid and is removed through the second opening. The cooling system is coupled to the frame and includes a radiator with a fluid therein and in fluid communication with the actuator and the power inverter such that the fluid flows to and from the actuator and to the power inverter, into the first opening of the housing, through the fluid passageway, and out of the second opening, and back to the radiator such that heat generated by the actuator, the first and second power modules, and the capacitor assembly is transferred to the fluid and respectively removed from the actuator and the power inverter.

### DESCRIPTION OF THE DRAWINGS

The present invention will hereinafter be described in conjunction with the following drawing figures, wherein like numerals denote like elements, and

FIG. 1 is a schematic view of an automobile including a power inverter;

FIG. 2 is an exploded isometric view of the power inverter of FIG. 1 illustrating a housing, a capacitor assembly, an input filter, and power module assemblies thereof;

FIG. 3 is an exploded isometric view of the housing, the capacitor assembly, and input filter of FIG. 2;

FIG. 4 is a cross-sectional view of the housing of FIG. 3 taken along line 4-4;

FIG. 5 is an exploded isometric view of the housing, the capacitor assembly, the input filter, and the power module assemblies of FIG. 2; and

FIG. 6 is a cross-sectional view of the housing, the capacitor assembly, and the input filter of FIG. 5 taken along line 6-6.

### DESCRIPTION OF AN EXEMPLARY EMBODIMENT

The following detailed description is merely exemplary in nature and is not intended to limit the invention or the application and uses of the invention. Furthermore, there is no intention to be bound by any expressed or implied theory presented in the preceding technical field, background, brief summary or the following detailed description.

The following description refers to elements or features being “connected” or “coupled” together. As used herein, unless expressly stated otherwise, “connected” means that one element/feature is directly joined to (or directly communicates with) another element/feature, and not necessarily mechanically. Likewise, unless expressly stated otherwise, “coupled” means that one element/feature is directly or indirectly joined to (or directly or indirectly communicates with) another element/feature, and not necessarily mechanically. However, it should be understood that although two elements may be described below, in one embodiment, as being “connected,” in alternative embodiments similar elements may be “coupled,” and vice versa. Thus, although the schematic diagrams shown herein depict example arrangements of elements, additional intervening elements, devices, features, or components may be present in an actual embodiment.

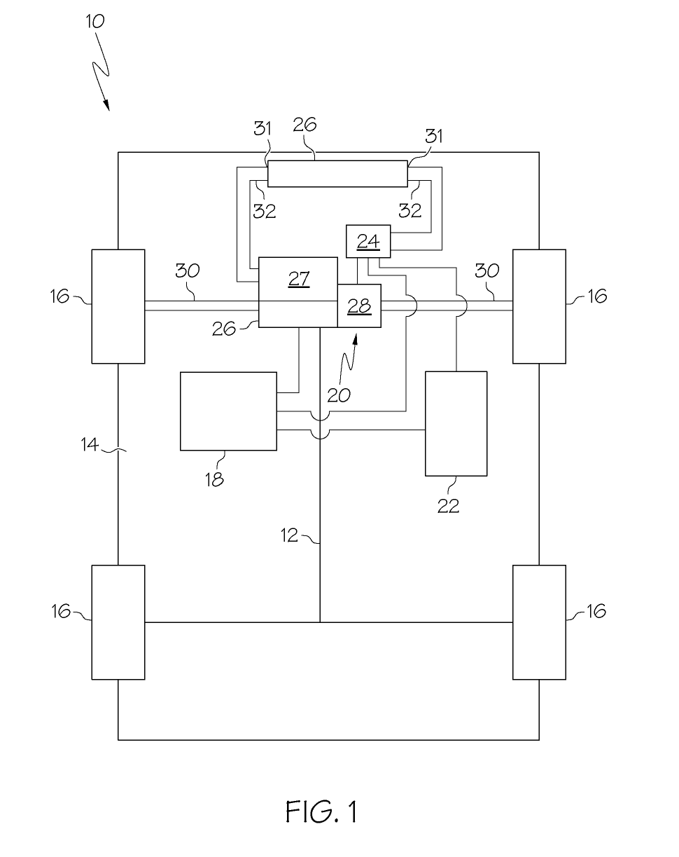

FIG. 1 to FIG. 6 illustrate a vehicular power inverter. The vehicular power inverter includes a housing with a cavity and a fluid passageway. The fluid passageway has first and second openings and is located on first and second sides (e.g., opposing sides) of the cavity. First and second power modules are connected to the housing on the respective first and second sides of the cavity. A capacitor assembly is placed within the cavity such that when heat is generated by the first and second power modules and the capacitor assembly and a fluid flows into the first opening, through the fluid passageway, and out of the second opening, at least some of the heat is transferred from the first and second power modules and the capacitor assembly to the fluid and is removed through the second opening.

FIG. 1 illustrates a vehicle 10, or automobile, according to one embodiment of the present invention. The automobile 10 includes a chassis 12, a body 14, four wheels 16, and an electronic control system 18. The body 14 is arranged on the chassis 12 and substantially encloses the other components of the automobile 10. The body 14 and the chassis 12 may jointly form a frame. The wheels 16 are each rotationally coupled to the chassis 12 near a respective corner of the body 14.

The automobile 10 may be any one of a number of different types of automobiles, such as, for example, a sedan, a wagon, a truck, or a sport utility vehicle (SUV), and may be two-wheel drive (2WD) (i.e., rear-wheel drive or front-wheel drive), four-wheel drive (4WD) or all-wheel drive (AWD). Although not shown, the vehicle 10 may also incorporate any one of, or combination of, a number of different types of engines, such as, for example, a gasoline or diesel fueled combustion engine, a “flex fuel vehicle” (FFV) engine (i.e., using a mixture of gasoline and alcohol), a gaseous compound (e.g., hydrogen and natural gas) fueled engine, a combustion/electric motor hybrid engine (i.e., a “hybrid vehicle”), and an electric motor. In an embodiment in which the automobile 10 is 4WD or AWD, the engine is mechanically coupled to all of the wheels. Additionally, as will be appreciated by one skilled in the art, the automobile 10 may include numerous additional components which are not shown in FIG. 1.

In the exemplary embodiment illustrated in FIG. 1, the automobile 10 is a hybrid vehicle, and further includes an actuator 20, a battery 22, an inverter 24, and a radiator 26. The actuator 20 includes a combustion engine 27 and an electric motor/generator 28. Although not shown, the electric motor 28 includes a transmission therein and is integrated with the combustion engine 27 such that both are mechanically coupled to at least some of the wheels 16 through one or more drive shafts 30. The radiator 26 is connected to the frame at an outer portion thereof and although not illustrated in detail, includes a multiple cooling channels that contain a cooling fluid (i.e., coolant) such as water and/or ethylene glycol (i.e., “antifreeze). In the example shown, the radiator 26 includes two inlet ports 31 and two outlet ports 32, each coupled (i.e., in fluid communication with) one of the combustion engine 27 and the inverter 24.

The electronic control system 18 is in operable communication with the actuator 20, the battery 22, and the inverter 24. Although not shown in detail, the electronic control system 18 includes various sensors and automotive control modules, or electronic control units (ECUs), and at least one processor and/or a memory 64 which includes instructions stored thereon (or in another computer-readable medium) for carrying out the processes and methods as described below.

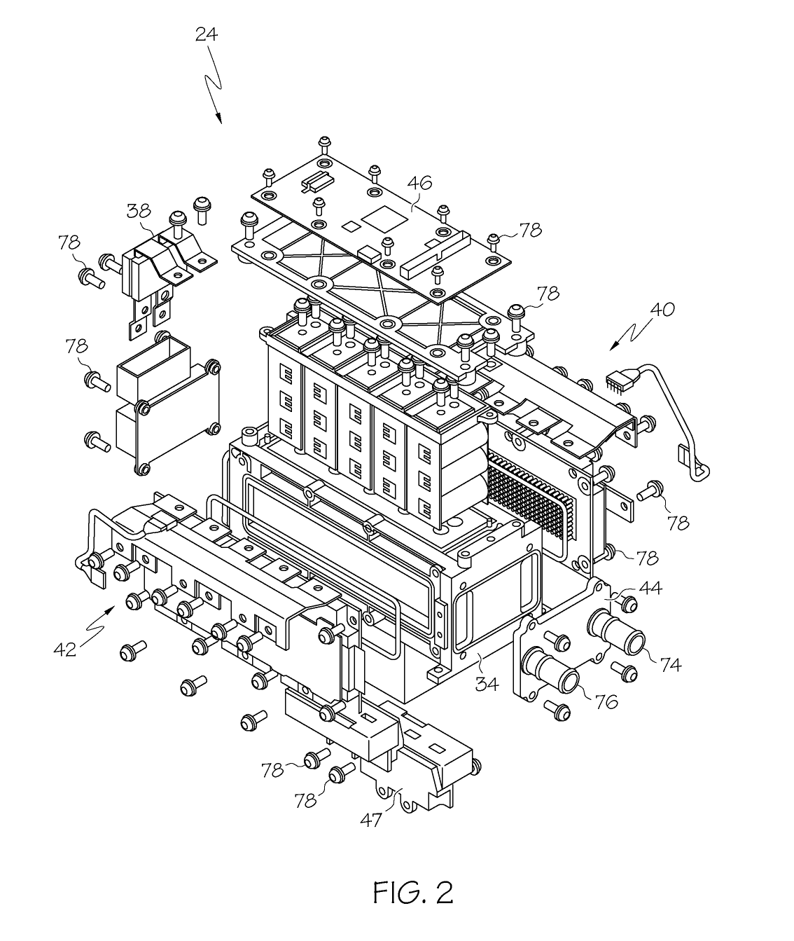

FIGS. 2-5 illustrates the inverter 24, according to one embodiment, in greater detail. Referring specifically to FIG. 2, the inverter 24 includes a housing 34 (or frame), a capacitor assembly 36, an input filter 38, first and second power module assemblies 40 and 42, a connector plate 44, a controller 46, and current sensors 47.

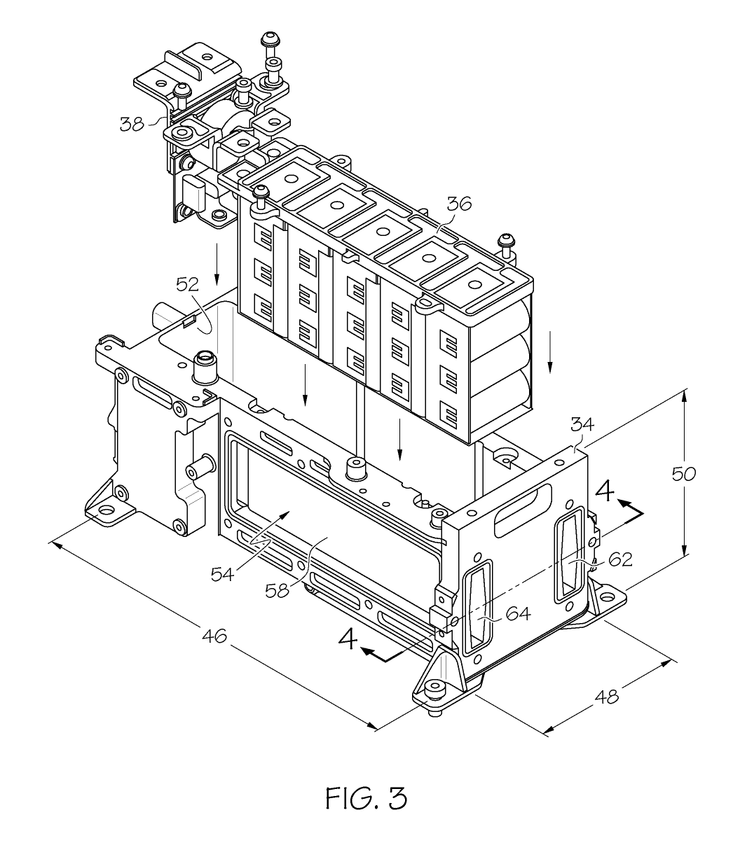

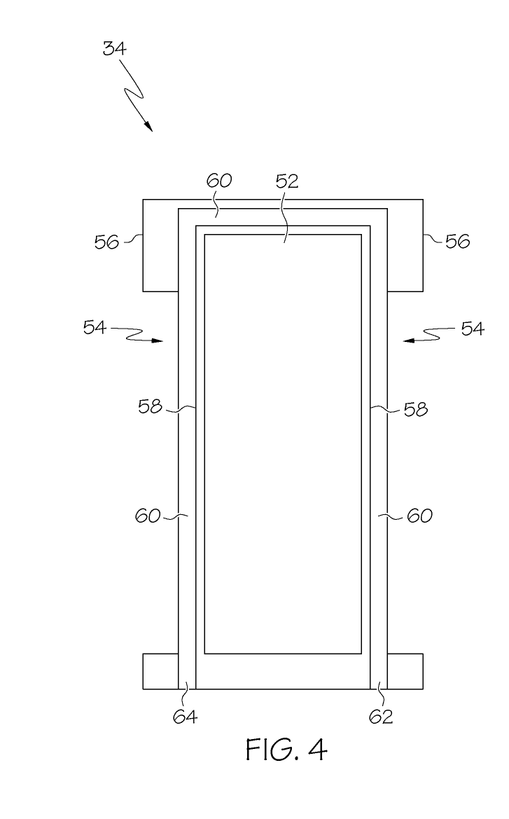

FIG. 3 illustrates the housing 34, the capacitor assembly 36, and the input filter 38. In the depicted embodiment, the housing 34 is substantially rectangular with, for example, a length 46 of between 8 and 15 inches, a width 48 of between 3 and 8 inches, and a height 50 of between 3 and 8 inches. In one embodiment, the housing 34 may have a volume of approximately 10 liters (L). The housing 34 is made of a thermally conductive material, such as aluminum or steel, and includes a cavity 52 defined at a central portion thereof. As shown, the cavity 52 may extend a majority of the length 46 and width 48, as well as substantially the entire height 50 of the housing 34 such that the top of the cavity 52 is exposed. Referring to FIG. 4 in combination with FIG. 3, the housing 34 also includes a power module opening 54 on each side thereof that extends from an outer surface 56 to a rectangular inner wall 58 that surrounds the cavity 52. The housing 34 also includes a fluid passageway 60 that extends through the housing 34 around a periphery of the inner wall 58. As shown in FIG. 4, the fluid passageway 60 is exposed at the power module openings 54 on both sides of the housing 34. In the depicted embodiment, the housing 34 further includes an inlet opening 62 and an outlet opening 64 through one end thereof adjacent to opposing ends of the fluid passageway 60.

Referring again to FIG. 3, the capacitor assembly 36 is substantially rectangular in shape with dimensions similar to those of the cavity 52 of the housing 34. Although not illustrated, the capacitor assembly 36 includes a set of conductor plates, or sets of conductive plates, in a spaced relationship and wound into coils to form a capacitor, or multiple capacitors, as is commonly understood. The input filter 38, or electromagnetic interference (EMI) filter, is connected to an end of the capacitor assembly 36, and in one embodiment, includes a Faraday coil that is electrically coupled to the capacitor(s) within the capacitor assembly 36. As indicated by the arrows in FIG. 3, the capacitor assembly 36 and the input filter 38 are placed in the cavity 52 of the housing 34. Although not shown, an epoxy or resin material may be placed in the cavity 52 with the capacitor assembly 36 and the input filter 38 to encase the assembly 36 and filter 38, as well as secure the assembly 36 and the filter 38 to the housing 34.

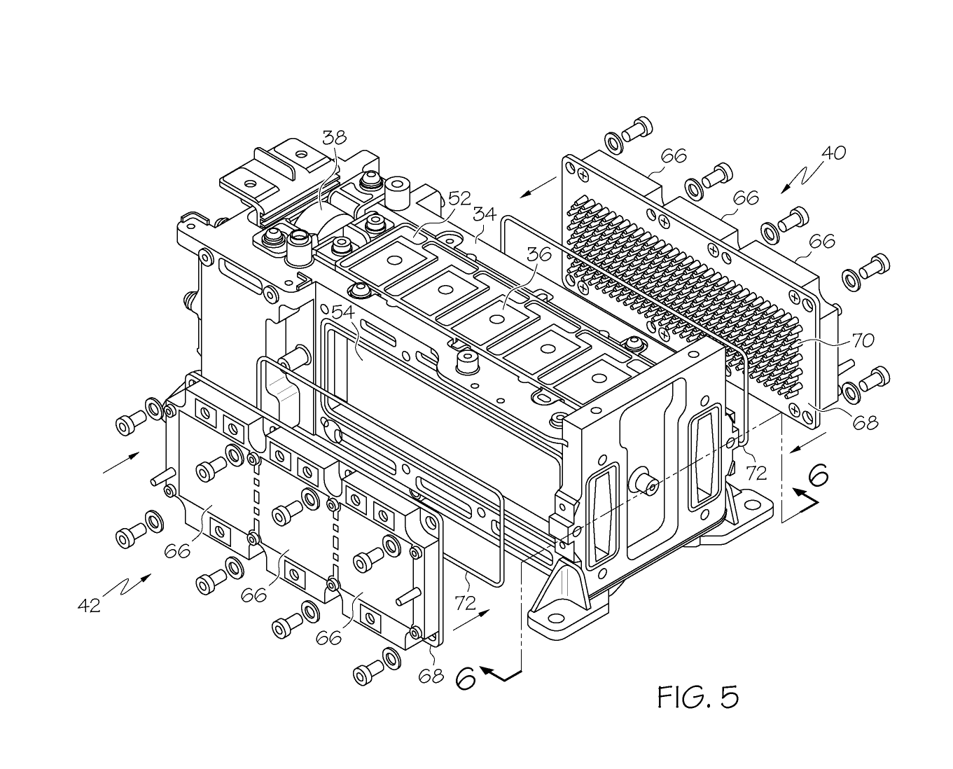

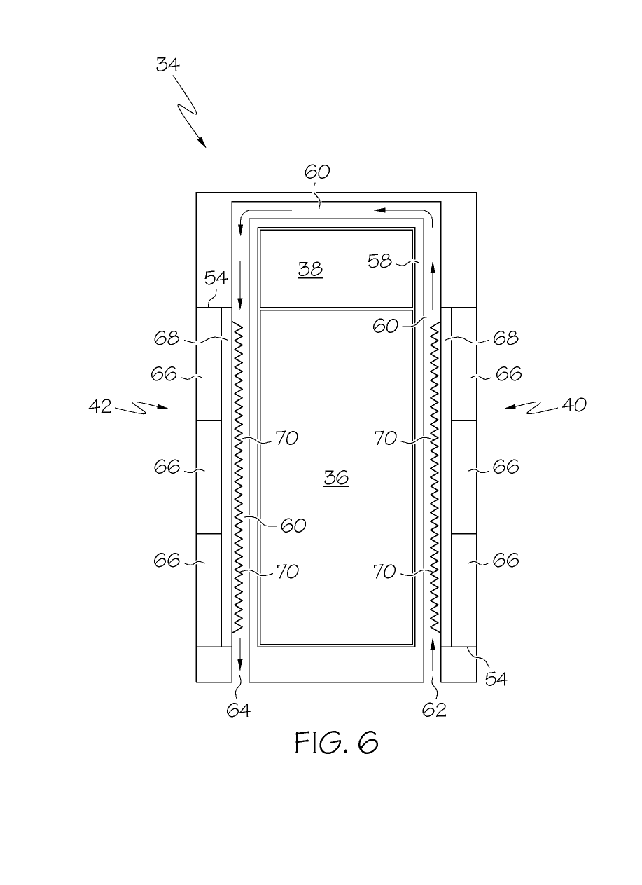

FIG. 5 illustrates the housing 34, with the capacitor assembly 36 and the input filter 38 placed in the cavity 52, and the power modules assemblies 40 and 42. In the embodiment illustrated, each power module assembly 40 and 42 includes three power module devices 66 mounted to a power module plate 68. Although not shown, each of the power module devices 66 may include a semiconductor substrate (e.g., silicon substrate) with an integrated circuit, having a plurality of semiconductor devices (e.g., transistors and/or switches), formed thereon. The power module plates 68 are sized to cover the power module openings 54, include an array of heat sink pins 70 extending from central portions thereof on the sides opposing the power module devices 66, are made of a thermally conductive material, such as aluminum. As indicated by the arrows in FIG. 5, the power module assemblies 40 and 42 are aligned with the power module openings 54 and secured to the opposing sides of the housing 34 with o-rings 72 positioned between the power module plates 68 and the outer surface 56 of the housing 34 around a periphery of the power module openings 54. The power module assemblies 40 and 42 are thus connected to the housing 34 in a “back-to-back” configuration on opposing sides of the capacitor assembly 36. As shown in FIG. 6, the power module assemblies 40 and 42 are secured such that the heat sink pins 70 on the power module plates 68 extend into the fluid passageway 60 while the power module plates 68, along with the o-rings 72, seal the fluid passageway 60 along the power module openings 54.

Referring again to FIG. 2, the connector plate 44 includes an inlet port 74 and an outlet port 76 and is secured to the end of the housing 34 opposite the input filter 38 such that the inlet port 74 and the outlet opening 64 are in fluid communication with the inlet opening 62 and the outlet port 76, respectively, shown in FIG. 6. The controller 46 is mounted to the housing 34 over the capacitor assembly 36 and includes a microprocessor, as is commonly understood, for controlling the operation of the inverter 24 as described below. Although not specifically illustrated, the current sensors 47 are in operable communication with (e.g., electrically coupled to) the controller 46. As shown in FIG. 2, the various components of the inverter 24 may be secured to the housing 34 with a plurality of threaded members 78 (i.e., screws).

During operation, still referring to FIG. 1, the vehicle 10 is operated by providing power to the wheels 16 with the combustion engine 27 and the electric motor 28 in an alternating manner and/or with the combustion engine 27 and the electric motor 28 simultaneously. In order to power the electric motor 28, direct current (DC) power is provided to the inverter 24, which converts the DC power into alternating current (AC) power, before the power is sent to the electric motor 24. To cool the combustion engine 27, the fluid within the radiator 26 is directed from the radiator 26 to the combustion engine 27. The fluid absorbs heat from the engine 27 and is returned to the radiator 26, where the fluid is cooled. In the embodiment shown, the same fluid provided to the combustion engine 27 is also provided to the inverter 24.

Referring to FIGS. 2 and 6, the fluid passes through the inlet port 74 on the connector plate 44 and enters the fluid passageway 60 through the inlet opening 62. In a first portion of the fluid passageway (i.e., adjacent to the first power module assembly 40 and the corresponding side of the capacitor assembly 36), heat generated by the first power module assembly 40 and conducted through the respective power module plate 68 to the heat sink pins 70, as well as heat generated by the capacitor assembly 36 and conducted through the inner wall 58 of the housing 34, is transferred to, or absorbed by, the fluid. Likewise, in a second portion of the fluid passageway 60 (i.e., adjacent to the second power module assembly 42 and the corresponding side of the capacitor assembly 36), heat generated by the second power module assembly 42 and conducted through the respective power module plate 68 to the heat sink pins 70, as well as heat generated by the capacitor assembly 36 and conducted through the inner wall 58 of the housing 34, is transferred to the fluid.

Additionally, heat generated by the input filter 38 and conducted through the inner wall 58 of the housing 34 is transferred to the fluid in a third portion of the fluid passageway (i.e., adjacent to the input filter 38 and interconnecting the first and second portions of the fluid passageway 60).

The fluid then exits the fluid passageway 60 through the outlet opening 64 and passes through the outlet port 76 on the connector plate 44. Referring again to FIG. 1, the fluid then returns to the radiator where it is cooled before returning to the combustion engine 27 and/or the inverter 24.

One advantage of the power inverter described above is that because of the back-to-back configuration of the power module assemblies, the fluid removes heat from multiple sides of the capacitor assembly, as well as the power module assemblies, simultaneously. Thus, the cooling provided by the fluid is increased, which allows for the use of a cooling fluid with an increased temperature. As a result, the fluid that is used to cool the combustion engine may also be used to cool the inverter. Another advantage is that the overall size of the inverter is minimized thus decreasing the distance between the power module assemblies, the capacitor assembly, and the input filter. The performance of the inverter is thereby improved as the inductances of the power connections are reduced.

Other embodiments may utilize the power inverter in other types of automobiles than hybrid vehicles and in conjunction with other electrical systems, such as a power steering system or an air conditioning system. The inverter may also be used in vehicles other than automobiles, such as aircraft and watercraft, or any system with multiple electrical systems that requires a conversion between DC and AC power.

While at least one exemplary embodiment has been presented in the foregoing detailed description, it should be appreciated that a vast number of variations exist. It should also be appreciated that the exemplary embodiment or exemplary embodiments are only examples, and are not intended to limit the scope, applicability, or configuration of the invention in any way. Rather, the foregoing detailed description will provide those skilled in the art with a convenient road map for implementing the exemplary embodiment or exemplary embodiments. It should be understood that various changes can be made in the function and arrangement of elements without departing from the scope of the invention as set forth in the appended claims and the legal equivalents thereof.

What is claimed is:

1. A vehicular power inverter comprising:
a housing having first and second openings therein and at least partially defining a cavity and a fluid passageway on first and second sides of the cavity;
first and second power modules connected to the housing on the respective first and second sides of the cavity; and
a capacitor assembly within the cavity such that when heat is generated by the first and second power modules and the capacitor assembly and a fluid flows into the first opening, through the fluid passageway, and out of the second opening, at least some of the heat is transferred from the first and second power modules and the capacitor assembly to the fluid and is removed through the second opening.

2. The vehicular power inverter of claim 1, wherein the housing comprises a thermally conductive material.

3. The vehicular power inverter of claim 2, wherein the first power module is on a first side of the housing and the second power module is on a second side of the housing.

4. The vehicular power inverter of claim 3, wherein the first side opposes the second side and the capacitor assembly comprises first and second sides.

5. The vehicular power inverter of claim 4, wherein the fluid passageway comprises a first portion and a second portion, the first portion being adjacent to the first side of the capacitor assembly and the first opening and the second portion being adjacent to the second side of the capacitor assembly and the second opening.

6. The vehicular power inverter of claim 5, wherein the first portion of the fluid passageway is between the first power module and the first side of the capacitor assembly and the second portion of the fluid passageway is between the second power module and the second side of the capacitor assembly.

7. The vehicular power inverter of claim 6, wherein the housing further comprises first and second ends, the first and second openings being in the first end.

8. The vehicular power inverter of claim 7, wherein the capacitor assembly further comprises first and second ends, the first end of the capacitor assembly being substantially adjacent to the first end of the housing, and the fluid passageway further comprises a third portion interconnecting the first and second portions of the fluid passageway and being substantially adjacent to the second end of the housing and the second end of the capacitor assembly.

9. The vehicular power inverter of claim 8, further comprising an input filter within the cavity and coupled to the capacitor assembly, the input filter being adjacent to the third portion of the fluid passageway such that heat generated by the input filter is transferred to the fluid and removed through the second opening.

10. The vehicular power inverter of claim 9, further comprising a controller in operable communication with the first and second power modules, the capacitor assembly, and the input filter.

11. An automotive power inverter comprising:
a housing having first and second opposing sides, first and second opposing ends, and first and second openings therethrough and at least partially defining a cavity having first and second opposing sides and a fluid passageway having first and second portions on the respective first and second opposing sides of the cavity and adjacent to the respective first and second openings, the housing comprising a thermally conductive material;
first and second power modules connected to the housing, the first power module being on the first side of the housing and the second power module being on the second side of the housing;
a capacitor assembly within the cavity, the capacitor assembly having first and second opposing sides and first and second opposing ends and being positioned and shaped such that the first end of the capacitor assembly is adjacent to the first end of the housing, the first portion of the fluid passageway is between the first side of the housing and the first side of the capacitor assembly, the second portion is between the second side of the housing and the second side of the capacitor housing so that when heat is generated by the first and second power modules and the capacitor assembly and a fluid flows into the first opening, through the fluid passageway, and out of the second opening, at least some of the heat is transferred from the first and second power modules and the capacitor assembly to the fluid and is removed through the second opening.

12. The automotive power inverter of claim 11, further comprising an input filter coupled to the capacity assembly and within the cavity, the input filter being adjacent to the third portion of the fluid passageway such that heat generated by the input filter is transferred to the fluid and removed through the second opening.

13. The automotive power inverter of claim 12, wherein the fluid passageway further comprises a third portion interconnecting the first and second portions such that the third portion is between the second end of the housing and the second end of the capacitor assembly.

14. The automotive power inverter of claim 13, wherein the housing and the capacitor assembly each have a length and a width, the respective length of each of the housing and the capacitor assembly being greater than the respective width of each of the housing and the capacitor.

15. The automotive power inverter of claim 14, further comprising a controller in operable communication with the first and second power modules, the capacitor assembly, and the input filter.

16. An automobile comprising:
a frame;
an actuator connected to the frame;
a power inverter coupled to the frame and the actuator, the power inverter comprising:
a housing having first and second openings therein and at least partially defining a cavity and a fluid passageway on first and second sides of the cavity;
first and second power modules connected to the housing on the respective first and second sides of the cavity; and
a capacitor assembly within the cavity such that when heat is generated by the first and second power modules and the capacitor assembly and a fluid flows into the first opening, through the fluid passageway, and out of the second opening, at least some of the heat is transferred from the first and second power modules and the capacitor assembly to the fluid and is removed through the second opening; and
a cooling system coupled to the frame, the cooling system having a radiator with a fluid therein, the radiator being in fluid communication with the actuator and the power inverter such that the fluid flows to and from the actuator and to the power inverter, into the first opening of the housing, through the fluid passageway, and out of the second opening, and back to the radiator such that heat generated by the actuator, the first and second power modules, and the capacitor assembly is transferred to the fluid and respectively removed from the actuator and the power inverter.

17. The automobile of claim 16, wherein the first side of the housing opposes the second side of the housing, the capacitor assembly comprises first and second sides, and the fluid passageway comprises a first portion and a second portion, the first portion being adjacent to the first side of the capacitor assembly and the first opening and the second portion being adjacent to the second side of the capacitor assembly and the second opening.

18. The automobile of claim 17, wherein the first portion of the fluid passageway is between the first power module and the first side of the capacitor assembly and the second portion of the fluid passageway is between the second power module and the second side of the capacitor assembly, the housing further comprises first and second ends, the first and second openings being in the first end, and the capacitor assembly further comprises first and second ends, the first end of the capacitor assembly being substantially adjacent to the first end of the housing, and the fluid passageway further comprises a third portion interconnecting the first and second portions of the fluid passageway and being between the between the second end of the housing and the second end of the capacitor assembly.

19. The automobile of claim 18, further comprising a plurality of wheels coupled to the frame, at least some of the plurality of wheels being mechanically coupled to the actuator.

20. The automobile of claim 19, wherein the actuator is an engine and further comprising an electric motor connected to the frame and electrically coupled to the power inverter, the at least some of the plurality of wheels being mechanically coupled to the actuator.
